(19) United States
(12) Patent Application Publication
(10) Pub. No.: US 2009/0160031 A1
(43) Pub. Date: Jun. 25, 2009

(54) Semiconductor Device and Method for Fabricating the Same

(76) Inventor: Dae Kyeun KIM, Yongin-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/234,544

(22) Filed: Sep. 19, 2008

(30) Foreign Application Priority Data
Dec. 24, 2007 (KR) 10-2007-0136562

(51) Int. Cl. H01L 29/06; H01L 21/31

(52) U.S. Cl. 257/622; 438/763; 257/E21.294; 257/E29.255

(57) ABSTRACT

A semiconductor device capable of preventing damage to a thermal oxide layer in a trench, and a method for fabricating the same are disclosed. The device includes a trench in a field region of a semiconductor substrate; a pad oxide layer on the surface of the semiconductor substrate outside the trench; a thermal oxide layer on sidewalls of the trench; a nitride layer covering the thermal oxide layer; an insulating layer filling the trench; and a spacer covering the thermal oxide layer outside the trench.

### RELATED APPLICATIONS

This application claims the benefit of Korean Patent Application No. 10-2007-0136562, filed on 24 Dec., 2007, which is hereby incorporated by reference as if fully set forth herein.

### BACKGROUND OF THE INVENTION

1. Field of the Invention

The present invention relates to a semiconductor device, and more particularly, to a semiconductor device capable of preventing damage to a thermal oxide layer, and a method for fabricating the same.

2. Discussion of the Related Art

In general, in order to form a transistor, a capacitor, etc. on a semiconductor substrate, the semiconductor substrate is formed with active regions that can apply an electric current to the devices and an isolation region that isolates the devices from one another.

One process for forming a field oxide layer involves a local oxidation of silicon (LOCOS) process including forming a pad oxide layer and a nitride layer on a semiconductor substrate, etching the nitride layer by a masking process, and forming a field oxide layer (hereinafter, referred to as an isolation oxide layer) on the etched area where an isolation oxide layer is to be formed. Additionally, one can also use a poly buffered (PBL) LOCOS process for growing the oxide layer by forming a polysilicon layer, which functions as a buffer, between the isolation oxide layer and nitride layer in the LOCOS process.

Recently, a shallow trench isolation (STI) process for forming an isolation region on a semiconductor substrate has been used. The STI process includes forming a trench with a predetermined depth in the semiconductor substrate, depositing an oxide layer over the trench, and etching the oxide layer in the unnecessary areas using a chemical mechanical polishing process. The present disclosure relates to a new process for forming an isolation oxide layer using the STI process.

A conventional method for forming an isolation oxide layer sequentially involves laminating a pad oxide layer on a semiconductor substrate, coating a nitride layer, which protects upper and lower layers, over the pad oxide layer, and forming a trench by masking and etching the nitride layer where the trench is to be formed.

FIG. 1 is a view illustrating a conventional semiconductor device formed with a shallow trench isolation (STI) layer.

Referring to FIG. 1, an isolation layer 4 is formed inside a trench 5 of the semiconductor substrate. Prior to that, a thermal oxide layer 2 is formed on the inner wall of the trench 5. Further, a liner nitride layer 3 is formed on the thermal oxide layer 2 before the isolation layer 4 is formed.

FIG. 1 illustrates the view after removing the pad nitride layer and pad oxide layer. The pad oxide layer is usually removed by wet etching.

In the etching process, a problem may arise in that the thermal oxide layer 2 exposed outside the trench 5 may be etched together with the pad oxide layer. In this case, a divot (an area where the thermal oxide layer 2 and/or the isolation layer 4 may be more deeply grooved than the semiconductor substrate 1 at the top where the semiconductor substrate 1 and isolation layer 4 meet) may be formed by removal of the thermal oxide layer 2 and/or the isolation layer 4 in the upper edge of the thermal oxide layer 2 and/or the uppermost part of the isolation layer 4. Thus, damage resulting from the pad oxide etching process may increase.

Such a divot can cause defects in the characteristics of a semiconductor device. Moreover, when a misalignment occurs in a subsequent metallization process, the isolation layer 4 may be directly etched, resulting in a possible contact being formed between the semiconductor substrate 1 and source and/or drain electrodes of the device, thereby causing defects in the device.

### SUMMARY OF THE INVENTION

Accordingly, the present invention is directed to a semiconductor device and a method for fabricating the same that substantially obviate one or more problems due to limitations and disadvantages of the related art.

An object of the present invention is to provide a semiconductor device equipped with a spacer capable of protecting a thermal oxide layer, and a method for fabricating the device.

Additional advantages, objects, and features of the invention will be set forth in part in the description which follows and in part will become apparent to those skilled in the art upon examination of the following or which may be learned from practice of the invention. The objectives and other advantages of the invention may be realized and attained by the structure(s) and/or method(s) particularly pointed out in the written description and claims hereof as well as the appended drawings.

To achieve these objects and other advantages and in accordance with the purpose of the invention, as embodied and broadly described herein, a semiconductor device may comprise a trench having a predetermined depth in a field region of a semiconductor substrate; a pad oxide layer on the surface of the semiconductor substrate outside the trench; a thermal oxide layer on the inner sidewalls of the trench; a nitride layer in the trench covering the thermal oxide layer; an insulating layer filling the trench; and a spacer covering the uppermost surface of the thermal oxide layer. In certain embodiments, the field region is for a shallow trench isolation (STI) structure, which may comprise the thermal oxide layer, the nitride layer, and the insulating layer. Also, the thermal oxide layer (or its uppermost surface) covered by the spacer may be outside the trench.

In another aspect of the present invention, a method for fabricating a semiconductor device may comprise forming a pad oxide layer over an entire surface of a semiconductor substrate; removing a portion of the pad oxide layer and semiconductor substrate in a field or isolation region of the semiconductor device to form a trench having a predetermined depth; forming a thermal oxide layer on inner sidewalls of the trench; forming a nitride layer covering the thermal oxide layer inside the trench; filling the trench with an isolation layer; removing the isolation layer outside of the trench by chemical mechanical polishing to expose the nitride layer; removing the nitride layer over the pad oxide layer; forming a passivation layer over the entire surface of the substrate; and etching the passivation layer to form a spacer covering au uppermost surface of the thermal oxide layer. In certain embodiments, the nitride layer initially covers the entire surface of the semiconductor substrate, including the pad oxide layer.

It is to be understood that both the foregoing general description and the following detailed description of the present invention are exemplary and explanatory and are intended to provide further explanation of the invention as claimed.

The method for fabricating a semiconductor device according to the present invention has the following effects. First, the spacer is capable of protecting and/or preventing damage to the thermal oxide layer formed on the semiconductor substrate. Second, the trench may be formed directly after patterning the pad oxide layer, without using a pad nitride layer, thereby increasing process margins of the photolithography and etching processes for forming the trench.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIG. 1 is a view illustrating a conventional semiconductor device formed with a shallow trench isolation layer; and

FIGS. 2A to 2H are cross-sectional drawings illustrating structures formed in a method for fabricating a semiconductor device according to embodiments of the present invention.

### DETAILED DESCRIPTION OF THE INVENTION

Reference will now be made in detail to the preferred embodiments of the present invention, examples of which are illustrated in the accompanying drawings.

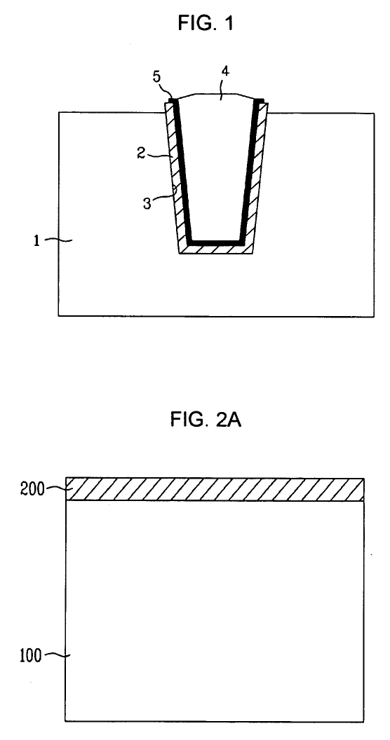

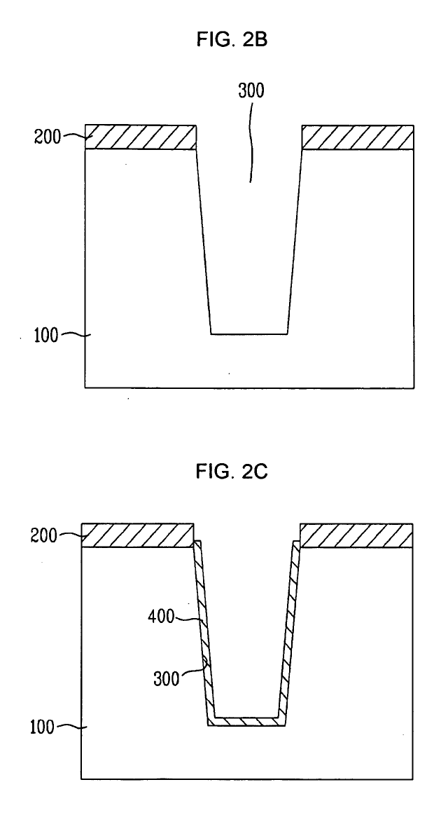

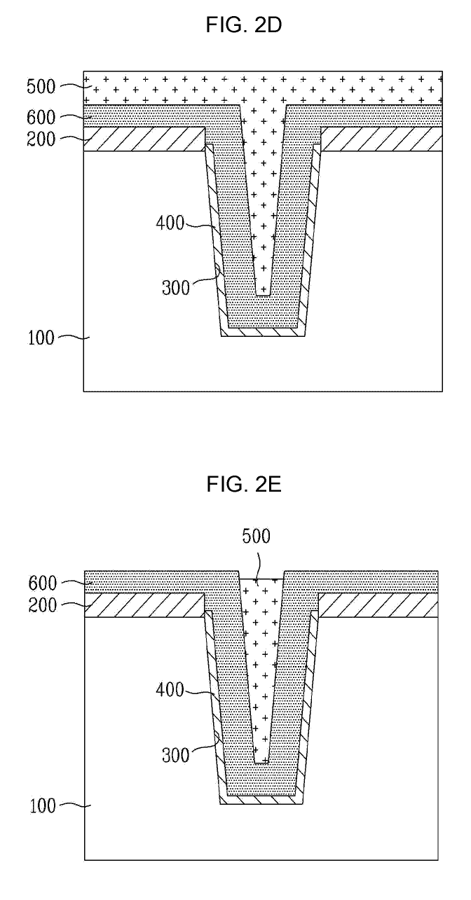

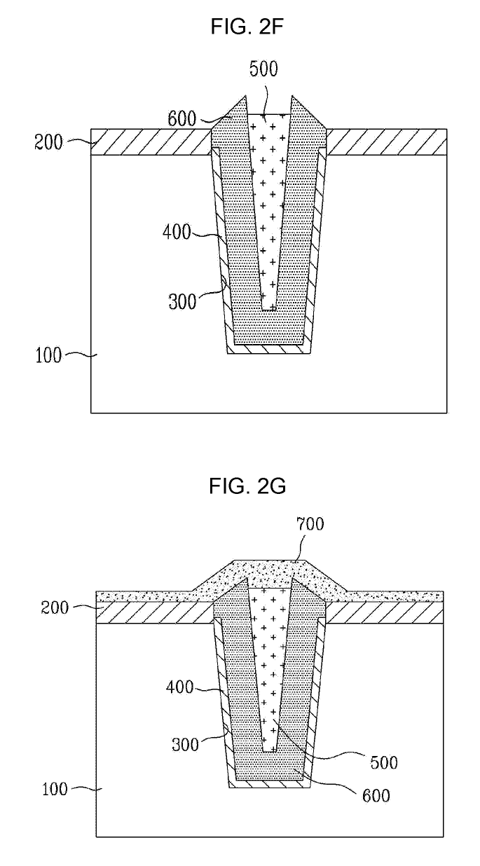

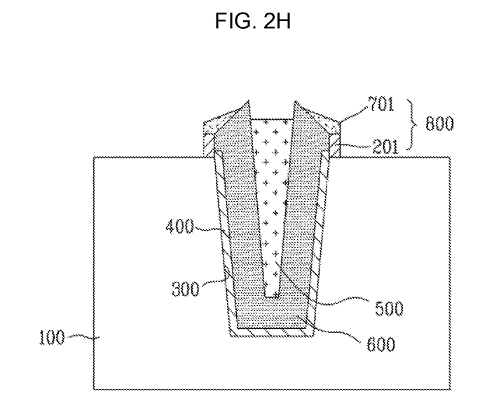

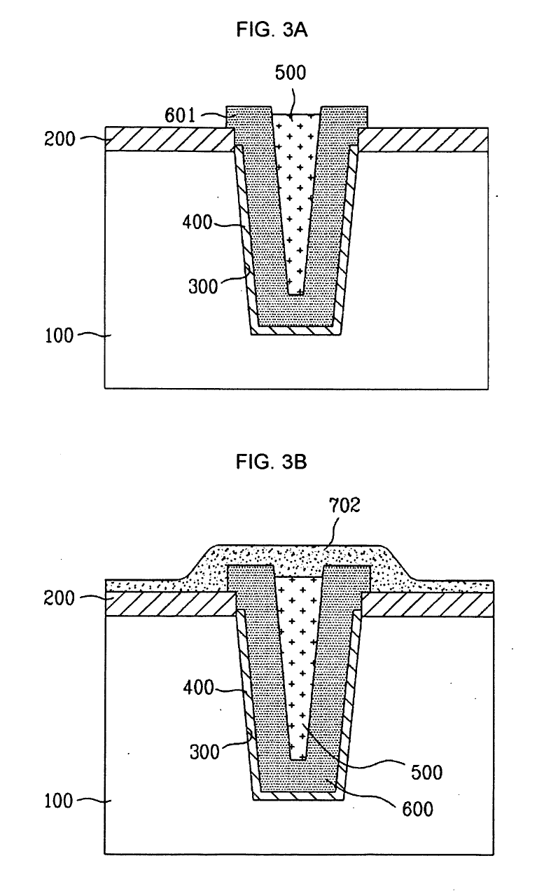

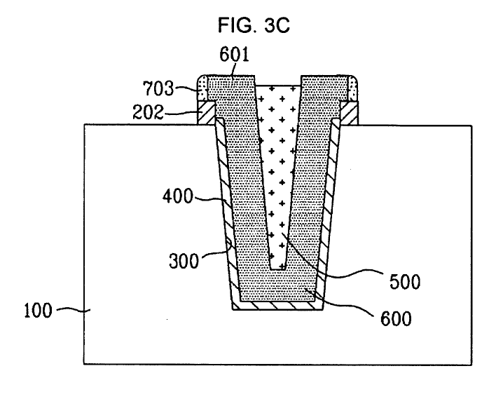

FIGS. 2A to 2H are cross-sectional drawings illustrating structures formed in a method for fabricating a semiconductor device according to embodiments of the present invention.

First, as shown in FIG. 2A, a pad oxide layer 200 is formed over the entire surface of a semiconductor substrate 100. The semiconductor substrate 100 may comprise silicon (e.g., single crystal silicon), and the pad oxide layer 200 may be formed by thermally oxidizing (e.g., by wet or dry thermal oxidation) the silicon substrate. Alternatively, the pad oxide layer 200 may be formed by depositing a silicon dioxide-based material (e.g., by chemical vapor deposition of silicon dioxide from a silicon source such as tetraethyl orthosilicate [TEOS] or silane and an oxygen source such as dioxygen and/or ozone). The pad oxide layer 200 may have a thickness of 100 to 200 Å.

Subsequently, as shown in FIG. 2B, a photoresist is coated over the pad oxide layer 200. Then, an exposure and development process is carried out using an exposure mask, which defines an area for forming a trench 300. The trench will become an isolation region. As a result, a photoresist pattern (not shown) for exposing the pad oxide layer on the isolation region is formed.

The unprotected part of the pad oxide layer 200 is subjected to anisotropic etching such as dry etching using the photoresist pattern as a mask to remove the pad oxide layer 200 and expose the semiconductor substrate 100. This will limit or define the isolation region and the active region.

Thereafter, the isolation region (i.e., the exposed semiconductor substrate 100), which is unprotected by the photoresist pattern or the pad oxide layer 200, is etched to a predetermined depth to form a trench 300. At this time, the trench 300 may be formed by anisotropic etching such as reactive ion etching (RIE) or plasma etching. The portions of the substrate on the isolation region that correspond to the top corners of the trench 300 may have a very steep inclination.

Thereafter, the photoresist pattern is removed by oxygen ashing (O₂ ashing), or the like. Then, the semiconductor substrate 100 is subjected to a washing process to remove impurities.

As shown in FIG. 2C, a sacrificial oxidation process may be performed to treat the damaged parts in the surface of the trench 300 caused by etching. In the sacrificial oxidation process, a thermal oxide layer 400 is grown on the inner wall of the trench 300 with a thickness of 150 to 200 Å, and then the oxide layer is removed by wet etching. The sacrificial oxidation process may also provide some desirable rounding at the uppermost corners of the trench 300. Subsequently, the oxidation process is performed again to grow the thermal oxide layer 400 on the inner wall of the trench 300 with a thickness of about 150 to 200 Å.

As shown in FIG. 2D, a nitride layer 600 is formed over the entire surface of the substrate 100, including the thermal oxide layer 400. At this time, the nitride layer 600 may be formed over the surface of the thermal oxide layer 400 inside the trench 300 and the entire surface of the pad oxide layer 200. The nitride layer 600 may be formed by chemical vapor deposition, from a silicon source such as silane (SiH₄) or tetrakis(dimethylamino)silane and an nitrogen source such as dinitrogen and/or ammonia). The nitride layer 600 may have a thickness, for example, of from 100 to 1500 Å (or any range of values therein, such as 500 to 1000 Å).

Thereafter, an insulating layer is coated or blanket-deposited on the pad nitride layer 600, including in the trench 300 so as to sufficiently fill the trench, thereby forming an isolation layer 500. At this time, the insulating layer may be formed by high density plasma chemical vapor deposition (HDP-CVD) of a silicon oxide (e.g., SiO₂). Due to the deposition characteristics, the density of HDP oxide deposited at the top corner areas of the trench 300 is lower than the other areas. In order to increase the density of the isolation layer 500, the semiconductor substrate 100 may be subjected to annealing (e.g., heating at a temperature sufficient to densify the deposited silicon oxide, such as at a temperature of from 600 to 1000° C.).

As shown in FIG. 2E, the isolation layer 500 is subjected to planarization such that the isolation layer 400 remains only inside the trench 300, and at the same time, the surface of the pad nitride layer 600 is exposed. At this time, the planarization may be carried out by chemical mechanical polishing (CMP).

As shown in FIG. 2F, the nitride layer 600 outside the isolation region is removed, for example by photolithography and etching (e.g., a selective etch process that removes silicon nitride preferentially to silicon dioxide). At this time, the etching process may be carried out by wet etching (e.g., with aqueous phosphoric acid, which may be heated to a temperature up to about 90° C. prior to use). Alternatively, and as shown in FIG. 3A, the nitride layer 600 outside the isolation region may be removed by photolithographic masking of the isolation region (not shown) and dry etching (e.g., a plasma etching or reactive ion etching process that removes silicon nitride preferentially to silicon dioxide). Preferably, a small amount of the etched nitride layer 601 remains over the pad oxide layer 200.

As shown in FIG. 2G, a passivation layer 700 is formed over the entire surface of the semiconductor substrate 100. The passivation layer 700 may comprise silicon nitride (SiNx) or another material that is selectively resistant to etching under one or more conventional sets of conditions for wet or dry etching silicon dioxide. A similar process for depositing a passivation layer 702 that is substantially identical to passivation layer 700 is shown in FIG. 3B. The passivation layer 700, 702 may be deposited by any conformal and/or blanket deposition technique described herein (e.g., chemical vapor deposition).

As shown in FIG. 2H, the passivation layer 700 and nitride layer 600 are patterned by an etching process to form a spacer 701 over the thermal oxide layer 400 exposed outside the trench 300. In one embodiment, the spacer 701 may be formed by anisotropic etching. When such a techniques is applied to the nitride layer 702 of FIG. 3B, spacer 703 is formed as shown in FIG. 3C. In another embodiment, the spacer 701 in FIG. 2H may be formed by photolithographic masking and dry etching.

After formation of the spacer 701/703, the exposed portion of the pad oxide layer 200 may be etched to leave a portion 201 (FIG. 2H) or 202 (FIG. 3A) of the pad oxide layer under the spacer 701/703. Thus, a thermal oxide-protecting spacer 800 may include a pad oxide layer portion 201/202 over the semiconductor substrate 100 and in contact with the thermal oxide layer 400 (e.g., one or more side surfaces thereof), and a passivation layer 701/703 formed on or over the pad oxide layer portion 201/202 (e.g., in contact with a top or uppermost surface of the pad oxide layer portion 201/202).

The pad oxide layer 200 may be etched by photolithographic masking (to protect the isolation layer 500) and a dry etching process that is selective for removing silicon dioxide over the material of the passivation layer 700/702. When the isolation layer 500 is covered with a thin passivation layer portion (not shown), the thin passivation layer portion may function as a mask to protect the isolation layer 500 from damage while etching the pad oxide layer 200. Alternatively, the isolation layer 500 may comprise a doped oxide (e.g., silicon dioxide doped with boron and/or phosphorous, fluorine, etc.) and completely fill the gap in the nitride layer 600 (see FIG. 2E), in which case an etchant that is at least slightly selective for removing the pad oxide layer 200 relative to the isolation layer 500 may remove a relatively insignificant amount of the isolation layer 500.

The layer 201/202 may comprise a portion of the pad oxide layer 200. Meanwhile, the passivation layer 701/703 may comprise silicon nitride.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A semiconductor device comprising:
a trench in an isolation region of a semiconductor substrate, the trench having a predetermined depth;
a pad oxide layer on the semiconductor substrate outside the trench;
a thermal oxide layer on inner sidewalls of the trench;
a nitride layer in the trench covering the thermal oxide layer;
an isolation layer filling the trench; and
a spacer covering an uppermost surface of the thermal oxide layer.

2. The device according to claim 1, wherein the spacer comprises:
a passivation layer in contact with uppermost surfaces of the nitride layer.

3. The device according to claim 2, wherein the passivation layer comprises silicon nitride.

4. The device according to claim 1, wherein the isolation layer comprises a high density plasma oxide.

5. The device according to claim 1, wherein the pad oxide layer contacts a side surface of the thermal oxide layer.

6. The device according to claim 5, wherein the pad oxide layer is under the spacer.

7. The device according to claim 6, wherein the pad oxide layer has a sidewall aligned with an edge of the spacer.

8. A method for fabricating a semiconductor device comprising:
forming a pad oxide layer over an entire surface of a semiconductor substrate;
removing a portion of the pad oxide layer and a portion of the semiconductor substrate in an isolation region of the semiconductor device to form a trench in the semiconductor substrate having a predetermined depth;
forming a thermal oxide layer on inner sidewalls of the trench;
covering the thermal oxide layer in the trench with a nitride layer;
filling the trench with an isolation layer;
removing a portion of the isolation layer by chemical mechanical polishing to expose the nitride layer;
removing the nitride layer over the pad oxide layer;
forming a passivation layer over an entire surface of the substrate; and
etching the passivation layer to form a spacer covering the thermal oxide layer outside the trench.

9. The method according to claim 8, wherein the passivation layer comprises silicon nitride.

10. The method according to claim 8, wherein removing the nitride layer comprises wet etching.

11. The method according to claim 8, wherein removing the nitride layer comprises dry etching.

12. The method according to claim 8, wherein etching the passivation layer comprises dry etching.

13. The method according to claim 8, wherein the spacer comprises:
a passivation layer over the semiconductor substrate, in contact with side surfaces of the thermal oxide layer.

14. The method according to claim 13, wherein the passivation layer comprises silicon nitride.

15. The method according to claim 8, further comprising removing the pad oxide layer exposed after removing the nitride layer, leaving a portion of the pad oxide layer under the spacer.

16. The method according to claim 8, wherein forming the thermal oxide layer comprises subjecting the surface of the trench to a sacrificial oxide process.

17. The method according to claim 8, wherein forming the thermal oxide layer comprises thermally oxidizing the sidewall surfaces of the trench.

18. The method according to claim 8, further comprising:
annealing the semiconductor substrate after filling the trench with the isolation layer.

19. The method according to claim 8, wherein, prior to filling the trench with the isolation layer, the nitride layer covers an entire surface of the semiconductor substrate, including the pad oxide layer.

20. The method according to claim 8, wherein removing the portion of the isolation layer exposes the nitride layer outside the trench.
